(19) United States
(12) Patent Application Publication
(10) Pub. No.: US 2023/0246563 A1
(43) Pub. Date: Aug. 3, 2023

(54) SEMICONDUCTOR MODULE WITH A DEPRESSION

(71) Applicant: Siemens Aktiengesellschaft, 80333 München (DE)

(72) Inventors: Roman KÖGLER, Nürnberg (DE); ALEXANDER LUFT, Nürnberg (DE); BERND ROPPELT, Unterhaid (DE); JENS SCHMENGER, Forchheim (DE); THOMAS SCHWINN, Herzogenaurach (DE)

(73) Assignee: Siemens Aktiengesellschaft, 80333 München (DE)

(21) Appl. No.: 18/023,024

(22) PCT Filed: Jun. 22, 2021
(86) PCT No.: PCT/EP2021/066971

§ 371 Date: Feb. 24, 2023

(30) Foreign Application Priority Data
Aug. 25, 2020 (DE) 20192526.0

(51) Int. Cl. H02M 7/00; H01L 23/36; H01L 23/04; H05K 1/02

(52) U.S. Cl. CPC H02M 7/003; H01L 23/36; H01L 23/04; H05K 1/0213

(57) ABSTRACT

A semiconductor assembly includes a semiconductor module designed for connection to a heat sink and having a surface which faces away from the heat sink and has a depression, a printed circuit board, and an electronic circuit arranged on the printed circuit board. The printed circuit board together with the electronic circuit is secured to the semiconductor module on the surface of the semiconductor module. The electronic circuit includes electronic components configured to protrude into the depression of the semiconductor module.

The invention relates to a semiconductor assembly, comprising a semiconductor module and an electronic circuit, the semiconductor module being designed to connect to a heat sink. The invention also relates to a power converter with such a semiconductor assembly.

The current trend in semiconductor development is at present mainly in the direction of reducing the size of existing systems and/or increasing the power at a fixed size. These can then be used for more powerful power converters. A power converter is an example of a power module in which a current and/or a voltage is converted with the aid of semiconductors.

In reducing the size, the focus has hitherto been on improved heat dissipation or cooling by means of more effective heat sinks or more powerful fans. Here, however, the limits have been reached as higher prices of, for example, a copper cooling body or the volume of a high-speed fan are not accepted by the market. Furthermore, existing, unneeded device volume is already exhausted via various optimization measures, as a result of which a further reduction is no longer possible or only possible with great effort.

This relates in particular to semiconductors of power electronics. These so-called power semiconductors have a current-carrying capacity of more than 1 ampere and voltages of more than 24 volts. The upper limit of these variables is in each case several thousand amperes or volts.

The reduction of the size of power converters can also be achieved by using SIC power semiconductors. Here, by means of higher clock frequencies of the power semiconductors, parts of the input filter can be in part significantly reduced in volume. A further option for reducing the size is to arrange an interior fan in the power converter. However, this is usually not desired for reasons of contamination in the interior of the devices.

The term semiconductor module refers to the structural unit which comprises the function of one or more semiconductor switches. These are then accommodated, for example, in a housing in order to form the structural unit.

The object of the invention is to improve a semiconductor assembly, in particular with regard to use in a power converter.

This object is achieved by a semiconductor assembly, comprising a semiconductor module and an electronic circuit, the semiconductor module being designed to connect to a heat sink, the electronic circuit being arranged on a printed circuit board, the printed circuit board together with the electronic circuit being secured to the semiconductor module on a surface of the semiconductor module facing away from the heat sink, the surface of the semiconductor module facing away from the heat sink having a depression, electronic components of the electronic circuit arranged on the printed circuit board protruding into the depression of the semiconductor module. This object is also achieved by a power converter with at least one such semiconductor assembly.

Further advantageous embodiments of the invention are specified in the dependent claims.

The invention is based, inter alia on the finding that the semiconductor assembly can be improved in that the electronic circuit is arranged at least on that side of the printed circuit board which is facing the semiconductor module. This is generally only possible for particularly small components such as resistors and capacitors in small SMD designs due to the small distance between the printed circuit board and the semiconductor module. The depression of the semiconductor module on the side facing the printed circuit board also permits the arrangement of larger components such as, for example, pulse capacitors, ceramic capacitors or film capacitors on the side of the printed circuit board facing the semiconductor module. These components then protrude into the depression of the semiconductor module. Thus, they do not have to be arranged on the side of the printed circuit board facing away from the semiconductor module. Such a condition otherwise makes it impossible to route the individual connections on an equipped printed circuit board. Installation space and printed circuit board surface can then be saved in that larger components can be provided at the location of the depression, which protrude into the depression and smaller components, in particular components in SMD technology, arranged at the location without a depression. This degree of freedom makes it possible to route individual signals. In this case, routing in the range of the semiconductor module in particular is possible through freely positioned terminals. Thus, it is advantageous to arrange the terminals as a function of the components of the electronic circuit.

As a result of the depression of the semiconductor module, it is possible to equip the printed circuit board on both sides. In other words, it is advantageous if the printed circuit board is equipped on both sides. Thus, two surfaces are available on the two sides of the printed circuit board for receiving electronic components. Due to the degree of freedom of the arrangement of large components on both sides of the printed circuit board in the immediate vicinity of the semiconductor module, the realization of an electronic circuit on a printed circuit board equipped on both sides and with small dimensions is possible. As a result, the printed circuit board surface on which the electronic circuit is arranged can in part be used twice and thus put to good use.

Due to the newly gained degree of freedom of placement of the components on the side of the printed circuit board facing the semiconductor module due to the depression in the semiconductor module, it is now possible to arrange components which are to be arranged close to the semiconductor module in terms of circuitry, even with short connection paths to the semiconductor assembly. This relates, for example, inter alia to the drive circuit of an IGBT or the low-inductance connection of capacitors to the intermediate circuit via short line or connecting paths.

The semiconductor module is a structural unit. This semiconductor module can comprise a single switch or a phase module with two switches. Likewise, further switches can be arranged in the semiconductor module, so that the semiconductor module forms a bridge circuit with four, six or even more switches.

Furthermore, with the standard heights of housing established today, a multiplicity of market requirements can be met in semiconductor modules. It has thus proven advantageous to provide such a standard height as a height for the semiconductor module of the proposed semiconductor assembly.

In addition, it has proven advantageous to distribute the terminals over the surface of the semiconductor module facing the printed circuit board. As a result, it is easier to arrange components in the layout of the electronic circuit, for example because of air/creepage distances and large trace widths for load connections, on the side of the printed circuit board facing the semiconductor module and to route the associated signals thereto.

Thus, by means of the depression in the semiconductor module and the printed circuit board, some of the electronic components of which protrude into the depression, it is possible to achieve clever interleaving of the semiconductor assembly and, in particular, to save printed circuit board surface on the printed circuit board in the case of two-sided assembly. The surface of the housing of the semiconductor module, also referred to as the semiconductor cover, advantageously receives one or more depressions, also referred to as indentations or pockets, at the points where the unused volume is present in the interior of the semiconductor module and in the region in which larger components have to be placed on the printed circuit board, in order to make the space usable for components on the printed circuit board. As a result, unused volume in the semiconductor module can be used for the components of the electronic circuit. In some cases, the height of the semiconductor module can also be reduced.

The design of the semiconductor module can also be used to provide one or more depressions at certain points of the cover. This advantage can be used particularly well if the terminals of the semiconductor module are distributed over the surface of the semiconductor module facing away from the heat sink. This degree of freedom can be used to arrange the terminals directly above the underlying chips and also to arrange the associated circuit parts of the electronic circuit in the immediate vicinity of the terminals. As a result, the electromagnetic compatibility (EMC) of the semiconductor assembly or of a power converter with such a semiconductor assembly can in part be significantly improved. Furthermore, commutation circuits are reduced, so that the switching behavior of the semiconductor module is improved, in particular when power electronics are used, and losses are reduced.

In a two-part embodiment of the housing of the semiconductor module, it is particularly advantageous to arrange the terminals in the cover. This simplifies the production of the corresponding semiconductor module and the semiconductor assembly.

The proposed semiconductor assembly results in a more compact structure, even in the case of devices such as power converters which are constructed from such semiconductor assemblies and other power modules. Alternatively, it is possible to switch to a higher power with a given design and size. Both result in an increase in the power density of the semiconductor assembly or of a power converter with such semiconductor assemblies. At the same time, the semiconductor assembly can be produced cost-effectively. As a result of the reduction in printed circuit board surface, the production becomes even more cost-effective than in the case of solutions known hitherto. Furthermore, the operating behavior and/or the possible uses of the semiconductor assemblies or of the power converters are also improved as circuit parts of the electronic circuit can be arranged spatially closer to the semiconductor module and thus to the power chips of the semiconductor module.

In an advantageous embodiment of the invention, the printed circuit board is connected to electrical terminals of the semiconductor module, in particular exclusively via electrical connections, for fastening via electrical connections. Due to the small dimensions and thus the small forces acting on the holder, it is possible to attach the printed circuit board of the electronic circuit to the semiconductor module solely via the electrical terminals. The distance between the printed circuit board and the semiconductor module is so small due to the depression even when the board is equipped on both sides that the forces on the terminals are so low that the terminals can take over the task of the mechanical connection in addition to the task of the electrical connection. If the electrical connection is dimensioned with regard to the electrical requirements, in particular the cross-section of the connection, then at the same time a sufficient mechanical strength of the connection is obtained on account of the short length of the connection. Furthermore, the embodiment of the pins in the area outside the depression is suitable for simplifying the assembly as the pins can find the holes of the printed circuit board more easily and unerringly on account of their length. Thus, no further devices need to be provided for mechanical connection.

In a further advantageous embodiment of the invention, the printed circuit board is connected to the semiconductor module without screw connections. As described above, no mechanically resilient connection between the semiconductor module and the printed circuit board is required any longer as the forces occurring are sufficiently mechanically resilient due to the small dimensions of the printed circuit board and the small distance between the printed circuit board and the semiconductor module even via simple connections such as, for example, plug connections or via the electrical terminals. Furthermore, these can be produced in a simple and cost-effective manner.

In a further advantageous embodiment of the invention, the terminals of the semiconductor module are arranged on the surface of the semiconductor module facing away from the heat sink outside the depression. The high structure in the area of the terminals gives the terminals a special strength. Furthermore, the embodiment of the pins in the area outside the depression is suitable for simplifying the assembly as the pins can find the holes of the printed circuit board more easily and unerringly on account of their length. This makes it possible, inter alia, to fasten the printed circuit board to the terminals by means of the connections. The required connection to the terminals is particularly short as the terminals are outside the area of the depression. In some cases, it is even possible to fasten the printed circuit board directly to the terminal of the semiconductor module. The corresponding connection is correspondingly short, so that only small forces have to be absorbed during fastening. Furthermore, it is also possible to design the housing of the semiconductor module at a standard height. The height is the distance between the surface where the heat sink is located and the surface of the semiconductor module facing the printed circuit board. As the terminals are located in the area outside the depression, the semiconductor modules with depression can also be used universally in existing applications. As a result of the economies of scale, the semiconductor assembly can then be produced cost-effectively.

In a further advantageous embodiment of the invention, the semiconductor module comprises the material silicon carbide and/or gallium nitrite. This semiconductor material permits the construction of semiconductor modules with a particularly high switching frequency. This is in the two or three-digit kHz range. As a result of the rapid switching, a particularly low-inductance control and connection to the intermediate circuit is also required. This can be realized in a particularly simple and cost-effective manner with the proposed arrangement of the semiconductor assembly. On the one hand, the intermediate circuit capacitors can be arranged at a small distance from the semiconductor module and the associated semiconductor chips. Furthermore, the modules of the electronic circuit required for control can also be arranged in the vicinity of the drive connections of the semiconductor module. Both allow safe and reliable operation of the semiconductor module with a particularly high switching frequency.

In a further advantageous embodiment of the invention, the semiconductor assembly comprises at least two semiconductor modules. With this arrangement, a bridge branch or even an entire half-bridge can be realized in a simple manner. As there are dependencies between the elements of a bridge branch or a half-bridge such as, for example, locks and locking times, it has proven advantageous to arrange these semiconductor modules in such a way that they are connected to exactly one printed circuit board of the electronic circuit. Especially in the case of a parallel connection of a plurality of semiconductor modules, it is particularly advantageous to connect these semiconductor modules to only one electronic circuit on account of the same control signals, as this circuit is constructed in a particularly simple manner on account of the same control signals for the semiconductor modules. A printed circuit board for a plurality of semiconductor modules can thus be used for control or supply. As a result, a particularly compact design of a power converter is possible.

In a further advantageous embodiment of the invention, the semiconductor assembly comprises the heat sink and a substrate of the semiconductor module is directly connected to the heat sink in a non-detachable manner. By applying the substrate, for example by soldering, sintering, gluing and/or printing, and a combination of these manufacturing possibilities, and thus of the semiconductor material on the heat sink, a particularly good heat transfer can be produced. Furthermore, the heat sink and the semiconductor module are connected to one another in a force-fitting manner. Regardless of how the semiconductor assembly is secured in a power converter, the electronic circuit can then also be mechanically connected to the semiconductor module by means of the connection to the electrical terminals of the semiconductor module. This is especially the case when a plurality of semiconductor modules is connected to a printed circuit board of the electronic circuit. It is thus particularly advantageous if at least two semiconductor modules are arranged on a heat sink. The heat sink thus also assumes the functionality of aligning and positioning the at least two semiconductor modules with respect to one another, so that a printed circuit board can then be connected to the electronic circuit with a plurality of semiconductor modules without having to absorb high forces impermissibly.

The invention is described and explained in more detail hereinafter with reference to the exemplary embodiments shown in the figures. It is shown in:

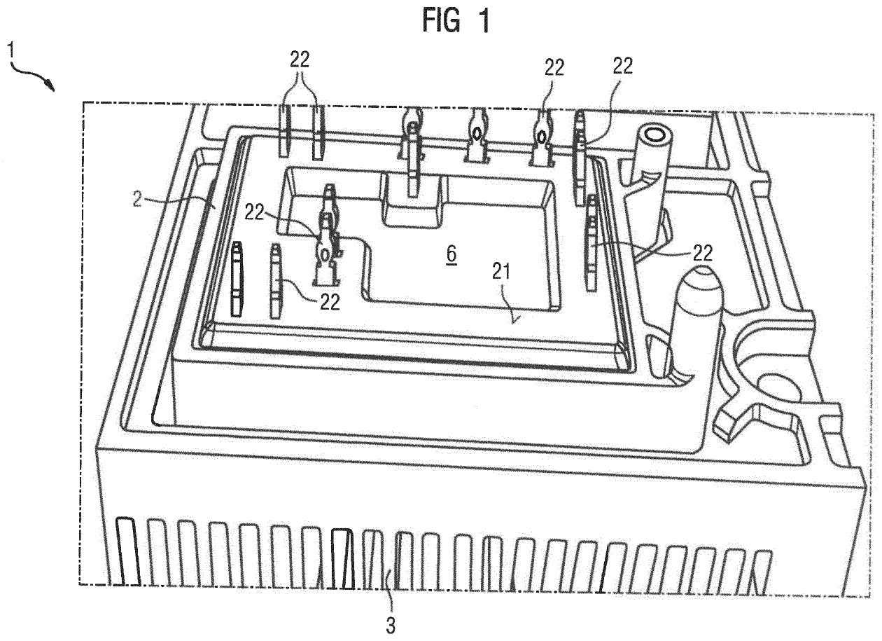

FIG. 1 a part of a semiconductor assembly,

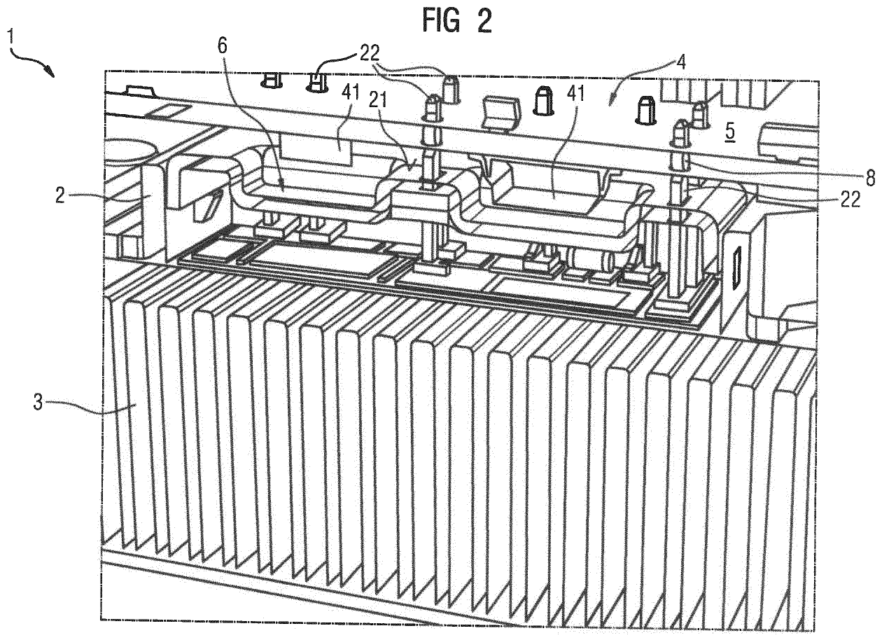

FIG. 2 a section through a semiconductor assembly, and

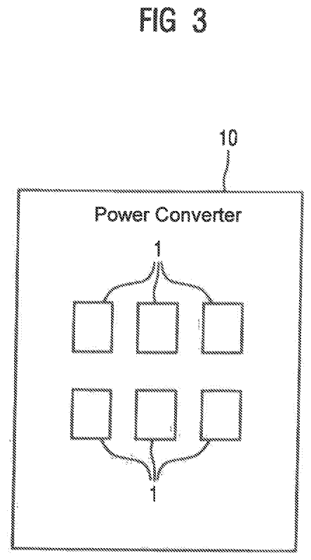

FIG. 3 a power converter.

FIG. 1 shows a part of a semiconductor assembly 1. In this exemplary embodiment, a semiconductor module 2 is connected to a heat sink 3. The connection can be designed, for example, in a non-detachable manner. This can be realized in that the substrate of the semiconductor module 2 has been applied directly to the heat sink 3 and thus the substrate of the semiconductor module 2 is directly connected to the heat sink 3. In this illustration, the semiconductor module 2 is designed in two parts. The housing has a base body and a cover, the cover being formed by the surface 21 of the semiconductor module 2 facing away from the heat sink. The terminals 22 of the semiconductor module 2 are also arranged on this surface 21, on which a printed circuit board 5 (not shown here) can be fastened to an electronic circuit 4. So that, on the one hand, the terminals 22 for fastening the printed circuit board 5 can be short in design, that is to say with a short length, and nevertheless the printed circuit board 5 can be equipped on both sides, a depression 6 is present on the surface 21 of the semiconductor module 2 facing away from the heat sink. FIG. 2 shows in a sectional view that electronic components 41 of the electric circuit 4 on the printed circuit board 5 can protrude into the depression 6 of the semiconductor module 2. This makes it possible to ensure that the distance between the semiconductor module 2 and the printed circuit board 5 can be selected to be so small even with the arrangement of larger components such as, for example, pulse capacitors, ceramic capacitors or electrolytic capacitors, that the printed circuit board 5 can be fastened to the terminals 22 of the semiconductor module 2 which form an electrical connection 8 between the printed circuit board 5 and the semiconductor module 2. In order to avoid repetition, reference is made to the description of FIG. 1 and to the reference characters introduced there.

FIG. 3 shows a power converter 10 which has a multiplicity of semiconductor assemblies 1.

In summary, the invention relates to a semiconductor assembly, comprising a semiconductor module and an electronic circuit, the semiconductor module being designed to connect to a heat sink. In order to improve the semiconductor assembly in particular with respect to the use of the semiconductor assembly in a power converter, it is proposed that the electronic circuit is arranged on a printed circuit board, the printed circuit board together with the electronic circuit being secured to the semiconductor module on a surface of the semiconductor module facing away from the heat sink, the surface of the semiconductor module facing away from the heat sink having a depression, electronic components of the electronic circuit arranged on the printed circuit board protruding into the depression of the semiconductor module. The invention also relates to a power converter comprising at least one such semiconductor assembly.

What is claimed is:

1.-8. (canceled)

9. A semiconductor assembly, comprising:
a semiconductor module designed for connection to a heat sink and having a surface which faces away from the heat sink and has a depression;
a printed circuit board; and
an electronic circuit arranged on the printed circuit board, with the printed circuit board together with the electronic circuit being secured to the semiconductor module on the surface of the semiconductor module, said electronic circuit comprising electronic components configured to protrude into the depression of the semiconductor module.

10. The semiconductor assembly of claim 9, wherein the semiconductor module comprises electrical terminals forming electrical connections between the printed board and the semiconductor module for fastening the printed board to the semiconductor module.

11. The semiconductor assembly of claim 10, wherein the printed board is fastened to the semiconductor module exclusively via the electrical connections.

12. The semiconductor assembly of claim 9, wherein the printed circuit board is connected to the semiconductor module without a screw connection.

13. The semiconductor assembly of claim 10, wherein the electrical terminals of the semiconductor module are arranged outside the depression on the surface of the semiconductor module.

14. The semiconductor assembly of claim 9, wherein the semiconductor module comprises at least one material selected from the group consisting of silicon carbide and gallium nitrite.

15. The semiconductor assembly of claim 9, further comprising at least two of said semiconductor modules for connection only to said heat sink.

16. The semiconductor assembly of claim 9, further comprising said heat sink, said semiconductor module comprising a substrate which is directly connected to the heat sink in a non-detachable manner.

17. A power converter, comprising a semiconductor assembly, said power converter comprising a semiconductor module designed for connection to a heat sink and having a surface which faces away from the heat sink and has a depression, a printed circuit board, and an electronic circuit arranged on the printed circuit board, with the printed circuit board together with the electronic circuit being secured to the semiconductor module on the surface of the semiconductor module, said electronic circuit comprising electronic components configured to protrude into the depression of the semiconductor module.

18. The power converter of claim 17, wherein the semiconductor module comprises electrical terminals forming electrical connections between the printed board and the semiconductor module for fastening the printed board to the semiconductor module.

19. The power converter of claim 18, wherein the printed board is fastened to the semiconductor module exclusively via the electrical connections.

20. The power converter of claim 17, wherein the printed circuit board is connected to the semiconductor module without a screw connection.

21. The power converter of claim 18, wherein the electrical terminals of the semiconductor module are arranged outside the depression on the surface of the semiconductor module.

22. The power converter of claim 17, wherein the semiconductor module comprises at least one material selected from the group consisting of silicon carbide and gallium nitrite.

23. The power converter of claim 17, wherein the semiconductor assembly comprises at least two of said semiconductor modules for connection only to said heat sink.

24. The power converter of claim 17, wherein the semiconductor assembly comprises said heat sink, said semiconductor module comprising a substrate which is directly connected to the heat sink in a non-detachable manner.
